(19) United States
(12) Patent Application Publication
(10) Pub. No.: US 2007/0153589 A1
(43) Pub. Date: Jul. 5, 2007

(54) VOLTAGE REGULATION CIRCUIT, PARTICULARLY FOR CHARGE PUMP

(75) Inventor: Francois Tailliet, Fuveau (FR)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMICROELECTRONICS SA, Montrouge (FR)

(21) Appl. No.: 11/610,046

(22) Filed: Dec. 13, 2006

(30) Foreign Application Priority Data
Dec. 13, 2005 (FR) 05 12574

(51) Int. Cl. G11C 11/34; G11C 16/06; G11C 7/10; G11C 5/14

(52) U.S. Cl. 365/189.06; 365/189.09; 365/185.23

(57) ABSTRACT

A voltage regulation device comprises a voltage regulator for regulating a direct voltage supplied by a voltage generator, the voltage regulator comprising means for stopping or activating the voltage generator depending on whether the voltage to be regulated is greater or lower than a setpoint voltage. The regulation device comprises a voltage limiter having a first threshold voltage greater than the setpoint voltage to clip a transient overvoltage greater than the first threshold voltage, appearing in the voltage to be regulated. Application can be made to the regulation of the high voltage used to program or erase a non-volatile memory.

### TECHNICAL FIELD

The present disclosure generally relates to a voltage regulation circuit, which can be used particularly but not exclusively at the output of a booster circuit.

### BACKGROUND INFORMATION

Booster circuits such as charge pumps enable a direct electric voltage greater than a determined supply voltage to be produced. In the field of integrated circuits, charge pumps are used to produce, for example, the high voltage Vpp for erasing and programming the floating-gate transistors of the electrically erasable and programmable memories (EEPROM, FLASH, FLASH-EEPROM, etc.).

FIG. 1 schematically represents a booster circuit HVCT comprising a charge pump CPCT supplying a load LD at an output Out with a boosted voltage Vpp. In the case of an EEPROM or FLASH memory, the charge pump feeds a capacitive and resistive load LD, the capacitance of which is equal to the sum of the gate stray capacitances of a set of floating-gate transistors to be erased or to be programmed simultaneously.

The charge pump CPCT is driven by clock signals Fx, Fn in opposite phase supplied by an oscillator OSC. The charge pump comprises a plurality of cascade-arranged pumping stages, the structure of which, well known to those skilled in the art, is not represented here. The charge pump CPCT receives at input a supply voltage Vcc in the order of 2 to 5 volts. The amplitude of the voltage Vpp depends on the total number of cascade-arranged pumping stages and is furthermore proportional to the voltage Vcc.

Typically, to program or erase an EEPROM memory, the booster circuit HVCT must be capable of supplying a voltage in the order of 15 to 18 V under a current of several tens of microamperes. If the voltage applied to the memory is too low, the memory cells programmed or erased are in an uncertain state. The result is that the memory will not be functional. On the contrary, if the voltage applied to the memory is too high, the transistors of the memory cells and of the high voltage stage unnecessarily suffer a stress that reduces the service life of the memory (aging of the transistors, floating-gate transistor gate oxide breakdown, etc.). For these reasons, it is recommended to limit to about 1 V the variations in the high voltage applied to the memory. These variations take into account the variations in temperature, supply voltage, consumption at output of the circuit booster, and memory manufacturing technology.

Now, the charge pump of a booster circuit is generally provided with a number of pumping stages greater than the number of stages theoretically sufficient, so as to be capable of withstanding a large range of working voltages and to offset the high internal impedance of the charge pump. As a result, after a starting period, the charge pump can deliver a voltage Vpp greater than the threshold Vppmax above which transistors to be erased or to be programmed could be damaged. Furthermore, the supply voltage Vcc can considerably fluctuate in relation to its nominal value taken into account during the design of the charge pump, and an increase in the voltage Vcc can cause a corresponding increase in the voltage Vpp above the threshold Vppmax.

A control of the voltage Vpp must therefore be provided, so as not to exceed the threshold Vppmax. As shown in FIG. 1, this control can be done by a simple voltage limiting circuit E1 connected in parallel between the output Out of the high voltage Vpp and the ground. The circuit E1 comprises for example three Zener diodes Z1, Z2, Z3 in series, each having a threshold voltage in the order of 5V. The conduction threshold voltage of the voltage limiter is the sum of the threshold voltages of each of the diodes, for example 15V. The booster circuit HVCT therefore continuously outputs in the circuit E1 the conduction of which rapidly increases from the conduction threshold. The circuit E1 thus enables the high voltage Vpp to be maintained at output of the booster circuit at the conduction threshold voltage that depends on the number and the characteristics of the Zener diodes of the circuit E1. The use of such a voltage limiter does however have a disadvantage from an energy point of view. The booster circuit HVCT outputs in the voltage limiter E1 a current that can be greater than the useful consumption in the circuit. The result is that the memory equipped with the voltage limiter has a high consumption in programming and erasing.

FIG. 2 schematically represents a booster circuit HVCT associated with a voltage regulation circuit RGCT1 having a better performance from the energy point of view than a simple voltage limiter. The circuit RGCT1 stops or activates the booster circuit HVCT depending on whether the voltage to be regulated is greater or lower than a setpoint voltage.

More precisely, the circuit RGCT1 comprises a voltage step-down circuit E2 having a conduction threshold voltage VE2. The circuit E2 receives at input the high voltage Vpp supplied by an output Out of the booster circuit HVCT, and supplies at output a stepped-down voltage Va. The voltage step-down circuit E2 is linked to the ground through a transistor M1 the source of which is connected to the ground. A reference voltage Vref is applied to the gate of the transistor M1. The transistor M1 behaves like a current source outputting a current Iref which biases the circuit E2. The circuit E2 steps down the voltage Vpp applied at input by a constant value equal to the conduction threshold voltage VE2 if the voltage Vpp is greater than the voltage VE2. The stepped-down voltage Va at output of the circuit E2 is applied to the input of an inverter I1 that supplies an activation input Run of the oscillator OSC of the booster circuit HVCT with a command signal Cmd.

FIG. 3A shows, in the form of timing diagrams, the operation of the regulation circuit RGCT1. FIG. 3A represents the shape of the two clock signals Fx and Fn in opposite phase, the variations in the voltage Vpp, and in the command signal applied to the input Run of the oscillator. When the oscillator OSC starts, the signal Cmd is on 1 and the voltage Vpp gradually increases until it reaches a setpoint voltage Vreg. When the boosted voltage Vpp reaches the voltage Vreg, the stepped-down voltage Va at the input of the inverter I1 is sufficient to cause the inverter I1 to switch. The output signal Cmd of the inverter I1 then changes to 0, which stops the oscillator OSC and thus deactivates the circuit CPCT. The setpoint voltage Vreg is therefore equal to VE2+VI1, VI1 being the switch voltage of the inverter I1. Therefore, the inverter I1 behaves like a comparator that supplies a binary signal on 0 or on 1 depending on whether the voltage applied at input is lower or greater than its switch voltage VI1.

While the booster circuit HVCT is deactivated, the voltage Vpp decreases until it reaches a value lower than the voltage Vreg. The voltage Va at the input of the inverter I1 goes back down below the switch voltage of the latter. The signal Cmd then returns to 1, which reactivates the oscillator and therefore the charge pump CPCT until the voltage Vpp again reaches the voltage Vreg. The circuit RGCT1 therefore performs an on/off-type regulation. The voltage Vreg is chosen to be lower or equal to the voltage Vppmax above which the memory can be damaged. The stability of the voltage regulation thus obtained is achieved by the internal capacitance of the circuit HVCT, which acts as an integrator.

The current likely to go through the circuit E2 is limited to the current Iref produced by the current source. However, this current is not limited in the circuit represented in FIG. 1. The regulation performed by the circuit RGCT1 is therefore advantageous in terms of current consumption and of flexibility of use, but has a relatively low instantaneous response. In particular, it does not enable a transient overvoltage to be absorbed at the output of the charge pump. This disadvantage is shown by the timing diagrams represented in FIG. 3B. An overvoltage at the supply voltage Vcc can cause a sudden increase S1 in the amplitude of one of the clock signals Fn, Fx. The sudden increase S1 might be instantly transferred in the form of an overvoltage S2, by the charge pump CPCT, to the voltage Vpp, mainly due to the fact that the response of the inverter I1 and the reaction of the booster circuit to a halt command are not instantaneous. The transfer of the overvoltage S1 to the voltage Vpp is also partly due to a capacitive coupling with the supply voltage Vcc, produced by a filter capacitor generally provided at output of the charge pump. The result is that the overvoltage S2 that thus appears in the voltage Vpp exceeds the setpoint voltage Vreg before the charge pump stops. In addition, the stopping of the charge pump (signal Cmd on 0) does not cause any clipping of the overvoltage S2 that can thus exceed the voltage Vppmax.

In summary, the voltage limiting device E1 represented in FIG. 1 provides good protection against the transient overvoltages, but is little efficient from the energy point of view. On the contrary, the regulation device RGCT represented in FIG. 2 is efficient from the energy point of view, but is not fast enough to clip all the transient overvoltages.

### BRIEF SUMMARY

One embodiment of the present invention provides a voltage regulation offering both good protection against transient overvoltages and low power consumption.

An embodiment of a voltage regulation device comprises a voltage regulator for regulating a direct voltage supplied by a voltage generator, the voltage regulator comprising means for stopping or activating the voltage generator depending on whether the voltage to be regulated is greater or lower than a setpoint voltage.

According to one embodiment of the present invention, the device comprises a voltage limiter having a first threshold voltage greater than the setpoint voltage to clip a transient overvoltage greater than the first threshold voltage, appearing in the voltage to be regulated.

According to one embodiment of the present invention, the voltage regulator comprises:
a voltage step-down circuit supplying, using the voltage to be regulated, a stepped-down voltage lower than the voltage to be regulated, and
a comparator for comparing the stepped-down voltage with a second threshold voltage, and for stopping or activating the voltage generator depending on whether the stepped-down voltage is greater or lower than the second threshold voltage.

According to one embodiment of the present invention, the voltage limiter comprises the voltage step-down circuit supplying the stepped-down voltage, and a voltage limiting circuit receiving the stepped-down voltage at input and having a conduction threshold voltage.

According to one embodiment of the present invention, the voltage step-down circuit comprises at least one Zener diode arranged between the output of the generator of the voltage to be regulated and a current source.

According to one embodiment of the present invention, the current source is arranged between the output of the voltage step-down circuit and the ground.

According to one embodiment of the present invention, the voltage limiting circuit comprises at least one Zener diode arranged between the output of the voltage step-down circuit and the ground.

According to one embodiment of the present invention, the voltage regulation device comprises a detector circuit for detecting a transient overvoltage.

According to one embodiment of the present invention, the voltage regulation device comprises means for storing a detected transient overvoltage.

According to one embodiment of the present invention, the detector circuit defines a detection voltage threshold that the voltage to be regulated must cross for an overvoltage to be detected, the detection voltage being between the setpoint voltage and the first threshold voltage.

One embodiment of the present invention also relates to an integrated circuit comprising a voltage generator supplying a voltage. According to an embodiment of the present invention, the integrated circuit comprises a voltage regulation device as defined above, for regulating the voltage supplied by the voltage generator.

According to one embodiment of the present invention, the voltage generator is a booster circuit.

According to one embodiment of the present invention, the voltage generator comprises a charge pump.

According to one embodiment of the present invention, the integrated circuit comprises a non-volatile memory that is supplied with high voltage by the voltage generator.

According to one embodiment of the present invention, the regulation device comprises a detector circuit for detecting an overvoltage, and the memory comprises a status register comprising a bit for storing the appearance of an overvoltage detected by the detector circuit.

According to one embodiment of the present invention, the memory comprises at least one memory cell reserved for storing the overvoltages detected by the detector circuit.

An embodiment of the present invention also relates to a method for regulating a direct voltage supplied by a voltage generator, the method comprises stopping or activating the voltage generator depending on whether the voltage to be regulated is greater or lower than a setpoint voltage.

According to an embodiment of the present invention, the method comprises clipping a transient overvoltage greater than a first threshold voltage, appearing in the voltage to be regulated, the first threshold voltage being greater than the setpoint voltage.

According to one embodiment of the present invention, the method comprises:
stepping down the voltage to be regulated so as to obtain a stepped-down voltage lower than the voltage to be regulated,
comparing the stepped-down voltage with a second threshold voltage, and
stopping or activating the voltage generator depending on whether the stepped-down voltage is greater or lower than the second threshold voltage.

According to one embodiment of the present invention, the voltage step-down circuit is biased by a current source.

According to one embodiment of the present invention, the method comprises detecting a transient overvoltage, by comparing the voltage to be regulated with a detection threshold voltage, the detection voltage being between the setpoint voltage and the first threshold voltage.

According to one embodiment of the present invention, the method comprises storing the detection of a transient overvoltage.

According to one embodiment of the present invention, the method comprises counting the transient overvoltages detected.

### BRIEF DESCRIPTION OF THE SEVERAL VIEWS OF THE DRAWINGS

These and other features of the present invention will be explained in greater detail in the following description of one or more embodiments of the present invention, given in relation with, but not limited to the following figures, in which:

FIG. 1 described above schematically represents a booster circuit equipped with a classic voltage limiter,

FIG. 2 described above schematically represents a booster circuit equipped with a classic voltage regulator,

FIGS. 3A and 3B described above show in the form of timing diagrams the operation of the regulator represented in FIG. 2,

FIG. 4 is a schematic diagram of a voltage regulator according to one embodiment of the present invention,

FIG. 5 represents one embodiment of the regulator according to the present invention, and

FIG. 6 represents an example of an embodiment of a booster circuit,

FIG. 7 represents in block form a memory equipped with the regulation device according to an embodiment of the present invention.

### DETAILED DESCRIPTION

In the following description, numerous specific details are given to provide a thorough understanding of embodiments. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The headings provided herein are for convenience only and do not interpret the scope or meaning of the embodiments.

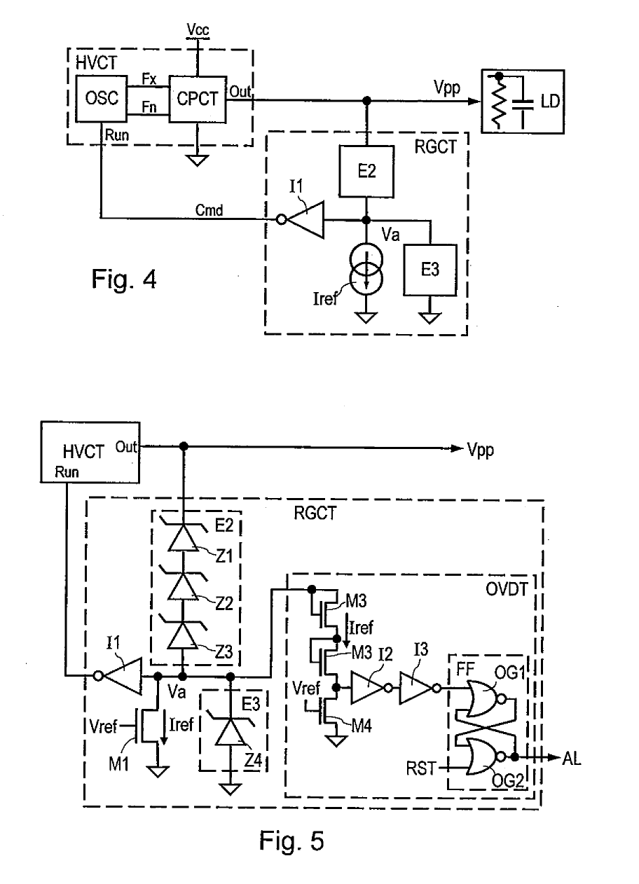

FIG. 4 is a schematic diagram of a voltage regulator RGCT according to an embodiment of the present invention. The voltage regulator RGCT is arranged between the output OUT of a booster circuit HVCT and the ground. The booster circuit HVCT comprises for example a charge pump CPCT powered by a supply voltage Vcc and supplying a high voltage Vpp. The voltage Vpp is applied to a load LD. The load LD is for example a capacitive and resistive load, the capacitance of which is formed by gate stray capacitances of memory cells to be erased or to be programmed, in the case of an EEPROM- or FLASH-type memory.

The voltage regulator RGCT of one embodiment comprises a voltage step-down circuit E2 that steps down the voltage Vpp by a constant value, a current source Iref and an inverter I1. The circuit E2 is connected at input to the output Out of the booster circuit HVCT, and at output, to a terminal of the current source Iref, the other terminal of which is connected to the ground. The input of the inverter I1 is connected to the output of the circuit E2. The output of the inverter I1 is connected to a control terminal Run of the booster circuit HVCT.

According to one embodiment of the present invention, the voltage regulator RGCT comprises a voltage limiting circuit E3 connected to the output of the voltage step-down circuit E2, in parallel with the current source Iref. The threshold voltage of the circuit E3 is chosen so that in the absence of any overvoltage, no current flows through the circuit E3.

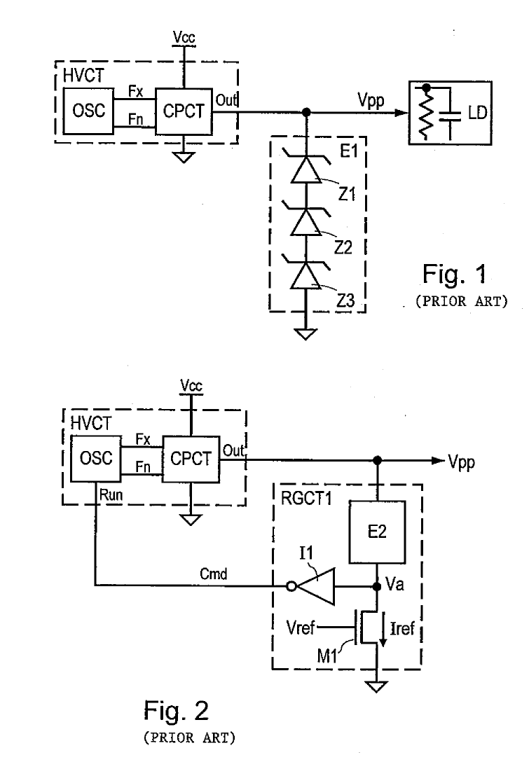

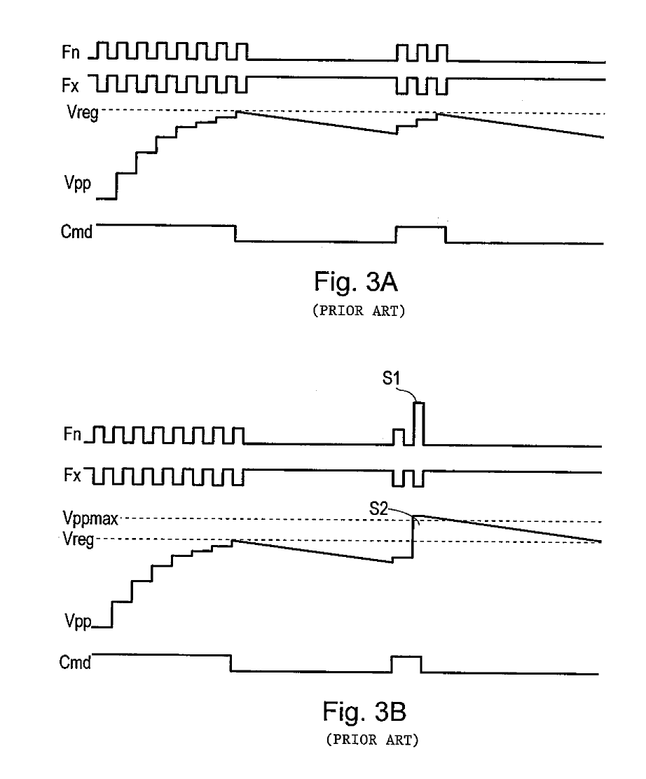

In the absence of any overvoltage, the voltage regulator RGCT of one embodiment therefore operates in the same way as the regulator RGCT1 represented in FIG. 2. The booster circuit HVCT is stopped when its output voltage Vpp exceeds a setpoint voltage Vreg, and activated when its output voltage returns below the voltage Vreg. The result is that the current consumption of the regulator RGCT is equivalent to the current consumption of the regulator RGCT1.

In the event that a transient overvoltage appears, the switch voltage VI1 of the inverter I1 is reached by the stepped-down voltage Va. The booster circuit HVCT is therefore stopped, but with a certain delay after the appearance of the overvoltage. The voltage Va at the input of the circuit E3 reaches the conduction threshold voltage VE3 of the latter which then becomes conductive. The result is that the overvoltage is evacuated into the two circuits E2 and E3 in series which together form a voltage limiting circuit having a threshold voltage Vth greater than the setpoint voltage Vreg. The circuits E2 and E3 are adapted to withstand significant currents.

The regulator RGCT according to one embodiment of the present invention therefore operates like a voltage limiter only in the event of transient overvoltage. It thus ensures an effective voltage regulation from the energy point of view, while being capable of absorbing the transient overvoltages.

FIG. 5 represents one embodiment of the voltage regulator RGCT according to the present invention. In FIG. 5, the voltage regulator RGCT comprises a voltage step-down circuit E2 receiving at input the voltage Vpp to be regulated at output of the booster circuit HVCT, as well as a voltage limiting circuit E3, a current source Iref and an inverter I1 connected to the output of the circuit E2. The output of the inverter I1 supplies the booster circuit HVCT with a command signal Cmd. The current source Iref of one embodiment comprises an NMOS-type transistor M1, the drain of which is connected to the circuits E2 and E3, and to the input of the inverter I1. The source of the transistor M1 is grounded and the gate receives a reference voltage Vref. The circuit E2 comprises for example three Zener diodes Z1, Z2, Z3 reverse mounted and arranged in series between the output Out of the booster HVCT and the drain of the transistor M1. The circuit E3 comprises a Zener diode Z4 reverse mounted between the drain of the transistor M1 and the ground.

As an example, the number of Zener diodes Z1, Z2, Z3 is three and they have a threshold voltage of 5V. The result is that the stepped-down voltage Va at the input of the inverter I1 is equal to Vpp−3×5 V. The switch voltage VE1 of the inverter I1 is for example equal to 1 V. The setpoint voltage Vreg of the voltage Vpp is therefore equal to 16 V. The threshold voltage of the Zener diode Z4 is chosen so that the boosted voltage Vpp never exceeds a voltage Vppmax. As an example, the conduction threshold voltage VE3 of the diode Z4 is chosen in the order of 5 V. The result is that the voltage Vpp cannot exceed a threshold voltage Vth equal to about 20 V.

The voltage regulator RGCT of one embodiment advantageously comprises an overvoltage detector circuit OVDT comprising an input connected to the drain of the transistor M1. The circuit OVDT of one embodiment comprises a group of several NMOS-type transistors M3, M4 in series, the transistors M3 being diode-mounted (drain connected to the gate). The group of transistors M3, M4, that comprises for example three transistors, is connected between the drain of the transistor M1 and the ground. The source of the transistor M4 is connected to the ground and the gate of this transistor receives the reference voltage Vref. The connection node between one of the transistors M3 and the transistor M4 is connected to an inverter I2 mounted in series with another inverter I3. The output of the inverter I3 is connected to the input of an RS-type flip-flop FF, the output of which supplies a signal AL indicating whether or not an overvoltage has been detected. The flip-flop FF is for example produced using two inverted OR-type logic gates OG1, OG2, the output of the inverter I3 being connected to the input of the gate OG1. The output of each of the gates OG1, OG2 is connected to an input of the other gate, the output of the gate OG2 supplying the signal AL. The flip-flop FF stores the state of the output of the inverter I3 until a reset signal RST is applied to an input of the gate OG2. The switch of the inverter I2 causes the inverter I3 to switch and therefore the state of the flip-flop FF and of the signal AL to change to 1.

The number n of transistors M3 and the inverter I2 are chosen so that only an overvoltage causes the inverter I2 to switch. In other words, the inverter I2 must switch when the voltage Vpp reaches a detection threshold voltage Vdet slightly greater than the setpoint voltage Vreg but lower than the threshold voltage Vth. Thus, the maximum value of the voltage Va at the input of the inverter I2 is equal to the maximum voltage at the input of the inverter I1 reduced by n times the threshold voltage of a transistor M3 and of the switch voltage of the inverter I2. In the example in FIG. 5, there are two transistors M3 that have, for example, a threshold voltage of 1 V. The inverter I2 is chosen so as to have a threshold voltage equal for example to 1 V. An overvoltage will therefore be detected if the boosted voltage Vpp exceeds the detection threshold voltage Vdet equal to the conduction threshold voltage VE2 of the circuit E2 increased by 3 V (2×1 V+1 V), i.e., 18 V, the setpoint voltage Vreg being equal to 16 V.

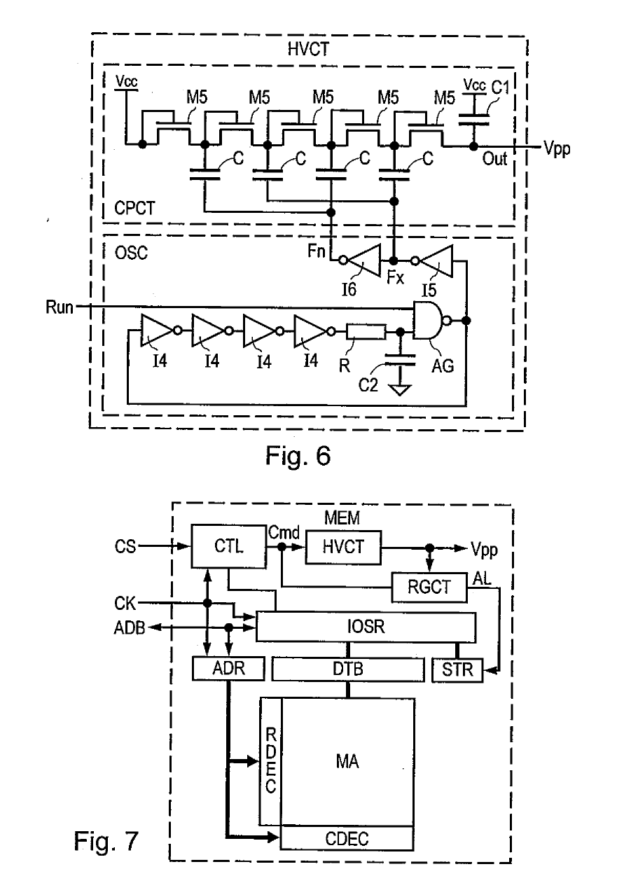

FIG. 6 represents an example of an embodiment of a booster circuit HVCT of the charge pump type, supplying the boosted voltage Vpp at an output Out. The circuit HVCT of an embodiment comprises a charge pump CPCT and a ring oscillator OSC.

The charge pump CPCT comprises several cascade-arranged pumping stages (4 stages in the example of the figure), each stage comprising a diode-mounted transistor M5 (gate connected to the drain) connected in parallel with a capacitor C. The drain of the transistor M2 of the first stage receives the supply voltage Vcc in the order of 2 to 5 V. The source of the transistor M2 of the last (fourth) stage is connected to the output terminal Out supplying the boosted voltage Vpp. The output terminal Out is linked to the supply voltage source Vcc through a filter capacitor C1. The capacitors C of the stages having an odd rank (first and third) in the circuit receive a first pumping signal Fx, while the capacitors of the stages having an even rank (second and fourth) receive a second pumping signal Fn.

The oscillator OSC comprises inverters I4 (for example 4) cascade-arranged with a resistor R, a capacitor C2 mounted in parallel between the resistor R and the ground, and an inverted AND-type gate AG one input of which is connected to the connection node between the resistor R and the capacitor C2. The output of the gate AG is looped back to the input of the first of the inverters I4. Another input of the gate AG is connected to the ON/OFF control terminal Run for activating/deactivating the circuit HVCT. The output of the gate AG is connected to two inverters I5, I6 mounted in series. The output of the inverter I5 supplies a first clock signal constituting the pumping signal Fx, and the output of the inverter I6 supplies a second clock signal in opposite phase with the first, constituting the second pumping signal Fn.

The amplitude of the voltage Vpp depends on the number of cascade-arranged pumping stages and is proportional to the voltage Vcc.

The voltage regulator according to one embodiment of the present invention can advantageously be integrated into a non-volatile memory, of the type for example comprising a serial input bus complying with the SPI or I2C standard.

FIG. 7 represents an embodiment of a memory MEM comprising a memory array MA, a control circuit CTL, a booster circuit HVCT supplying a high voltage Vpp, an address register ADR, a data register DTB, an input/output register IOSR, a status register STR, a line decoder RDEC and a column decoder CDEC. The control circuit CTL receives from the external environment a selection signal CS and a clock signal CK. The circuit CTL controls the register IOSR, the circuit HVCT, and the status register STR. The registers IOSR and ADR are connected outside the memory by a serial bus ADB, for example of SPI or I2C type. The registers IOSR and ADR are paced by the clock signal CK. In write mode, the register ADR receives an address of memory cells from the external environment by the serial bus ADB, and the register IOSR receives data to be stored in the memory array MA. In read mode, the register ADR receives a read address from the bus ADB and the register IOSR receives from the memory array MA a datum read, to be sent on the bus ADB in response to a read command. The data read or to be written transit in the register DTB between the memory array MA and the register IOSR. The status register contains information concerning the state of the memory MEM. The address contained in the register ADR is used to control the decoders RDEC and CDEC that enable memory cells that are to be programmed, to be erased or to be read, to be selected according to the address supplied by the address register.

According to one embodiment of the present invention, the booster circuit HVCT of the memory MEM is associated with a voltage regulator RGCT as previously described with reference to FIG. 5. The voltage regulator controls the booster circuit HVCT and supplies a signal AL indicating whether or not an overvoltage is detected by the circuit OVDT. In the case of an SPI-type bus, the state of the signal AL is advantageously stored by a bit of the status register STR. In this case, the flip-flop FF represented in FIG. 5 is not necessary. In the case of a bus I2C, the state of the signal AL can be stored in a memory cell outside the normal addressing field of the memory MEM. The state of the signal AL can thus be read, by controlling the read access to a specific address of the memory.

Providing an overvoltage detection bit in a status register or in a memory cell of the memory MEM facilitates the debugging of an application subject to overvoltage requirements on the supply voltages, or to electrostatic discharges. Indeed, certain applications can cause many reliability rejections due to breakdowns of gate oxide of the floating-gate transistors, subjected to the high voltage Vpp. Certain breakdowns result from an internal transfer of overvoltages appearing in the external supply voltages and particularly the voltage Vcc. Providing an overvoltage detection bit enables the conditions causing an overvoltage to be determined, and therefore helps such overvoltages to be removed.

Provision can be made for a command executable by the control circuit CTL enabling the overvoltage detection bit in the status register STR to be set.

Alternatively, all the overvoltages detected by the circuit OVDT are stored in memory cells of the memory array MA, for example in the form of a counter counting all the dangerous overvoltages suffered by the memory. Thanks to this counter, it is possible to assess the history of the memory.

It will be understood by those skilled in the art that various other alternative embodiments and applications of the present invention are possible. In particular but not exclusively, it is not necessary for the voltage step-down and voltage limitation functions to use the same components (Zener diodes). These functions can be totally separated, even if this solution is not optimum in terms of number of components.

Other means than the one previously described do exist for detecting the appearance of an overvoltage. Indeed, the appearance of an overvoltage can for example be detected by measuring a current in the voltage limiting circuit E2.

Various applications of embodiments of the present invention may also be made. Although an application of an embodiment of the present invention to the control of the voltage Vpp for programming and erasing memory cells is described above, it goes without saying that another embodiment of the present invention can be applied more generally to a direct voltage generator, and not necessarily to a booster.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

The above description of illustrated embodiments, including what is described in the Abstract, is not intended to be exhaustive or to limit the invention to the precise forms disclosed. While specific embodiments and examples are described herein for illustrative purposes, various equivalent modifications are possible within the scope of the invention and can be made without deviating from the spirit and scope of the invention.

These and other modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. A voltage regulation device, comprising:
a voltage regulator to regulate a direct voltage supplied by a voltage generator, the voltage regulator including means for stopping or activating the voltage generator depending on whether the voltage to be regulated is greater or lower than a setpoint voltage, wherein the voltage regulator includes a voltage limiter having a first threshold voltage greater than the setpoint voltage to clip a transient overvoltage greater than the first threshold voltage, appearing in the voltage to be regulated.

2. The device according to claim 1 wherein the voltage regulator comprises:
a voltage step-down circuit to supply, using the voltage to be regulated, a stepped-down voltage lower than the voltage to be regulated; and
a comparator to compare the stepped-down voltage with a second threshold voltage, and to stop or activate the voltage generator depending on whether the stepped-down voltage is greater or lower than the second threshold voltage.

3. The device according to claim 2 wherein the voltage limiter comprises the voltage step-down circuit to supply the stepped-down voltage, and a voltage limiting circuit to receive the stepped-down voltage at input and having a conduction threshold voltage.

4. The device according to claim 2 wherein the voltage step-down circuit comprises at least one Zener diode arranged between an output of the generator of the voltage to be regulated and a current source.

5. The device according to claim 4 wherein the current source is arranged between an output of the voltage step-down circuit and ground.

6. The device according to claim 3 wherein the voltage limiting circuit comprises at least one Zener diode arranged between an output of the voltage step-down circuit and ground.

7. The device according to claim 1, further comprising a detector circuit to detect the transient overvoltage.

8. The device according to claim 7, further comprising means for storing a detected transient overvoltage.

9. The device according to claim 7 wherein the detector circuit defines a detection voltage threshold that the voltage to be regulated must cross for the overvoltage to be detected, the detection voltage threshold being between the setpoint voltage and the first threshold voltage.

10. An integrated circuit, comprising:
a voltage generator to supply a voltage; and
a voltage regulation device coupled to the voltage generator to regulate the voltage supplied by the voltage generator, the voltage regulation device including:
a circuit to stop or activate the voltage generator based on whether the voltage to be regulated is greater or lower than a setpoint voltage; and
a voltage limiter coupled to the circuit and having a first threshold voltage greater than the setpoint voltage to clip a transient overvoltage, greater than the first threshold voltage, that appears in the voltage to be regulated.

11. The integrated circuit according to claim 10 wherein the voltage generator is a booster circuit.

12. The integrated circuit according to claim 10 wherein the voltage generator includes a charge pump.

13. The integrated circuit according to claim 10, further comprising a non-volatile memory that is supplied with high voltage by the voltage generator.

14. The integrated circuit according to claim 13 wherein the voltage regulation device includes a detector circuit to detect an overvoltage, and the memory includes a status register having a bit to store an appearance of an overvoltage detected by the detector circuit.

15. The integrated circuit according to claim 14 wherein the memory includes at least one memory cell reserved to store the overvoltage detected by the detector circuit.

16. A method for regulating a direct voltage supplied by a voltage generator, the method comprising:
stopping or activating the voltage generator depending on whether the voltage to be regulated is greater or lower than a setpoint voltage; and
clipping a transient overvoltage greater than a first threshold voltage, appearing in the voltage to be regulated, the first threshold voltage being greater than the setpoint voltage.

17. The method according to claim 16, further comprising:
stepping down the voltage to be regulated so as to obtain a stepped-down voltage lower than the voltage to be regulated;
comparing the stepped-down voltage with a second threshold voltage; and
stopping or activating the voltage generator depending on whether the stepped-down voltage is greater or lower than the second threshold voltage.

18. The method according to claim 17 wherein said stepping down the voltage is performed by a voltage step-down circuit, and wherein the voltage step-down circuit is biased by a current source.

19. The method according to claim 16, further comprising detecting the transient overvoltage by comparing the voltage to be regulated with a detection threshold voltage, the detection threshold voltage being between the setpoint voltage and the first threshold voltage.

20. The method according to claim 19, further comprising storing the detection of the transient overvoltage.

21. The method according to claim 19, further comprising counting a plurality of transient overvoltages detected.

22. A voltage regulation system, comprising:
a voltage regulator to regulate a voltage provided by a voltage generator, the voltage regulator including circuitry to stop or activate the voltage generator depending on whether the voltage to be regulated is greater or lower than a setpoint voltage; and
a voltage limiter coupled to said circuitry and having a first threshold voltage greater than the setpoint voltage, the voltage limited being adapted to control said circuitry and to clip a transient overvoltage, greater than the first threshold voltage, that appears in the voltage to be regulated.

23. The system of claim 22 wherein said voltage generator includes:
a charge pump to generate said voltage to be regulated; and
an oscillator coupled to said charge pump to drive said charge pump, said oscillator further being coupled to said circuitry of the voltage regulator to receive a command signal from said circuitry.

24. The system of claim 22 wherein said voltage limiter includes a voltage step-down circuit to supply, using the voltage to be regulated, a stepped-down voltage lower than the voltage to be regulated, and wherein said circuitry of the voltage regulator includes a comparator coupled to the voltage step-down circuit to receive the stepped-down voltage and to compare the stepped-down voltage with a second threshold voltage, the comparator being adapted to generate the command signal to stop or activate the voltage generator depending on whether the stepped-down voltage is greater or lower than the second threshold voltage.

25. The apparatus of claim 24 wherein the voltage limiter further includes a voltage limiting circuit coupled to the voltage step-down circuit to receive the stepped-down voltage at input, the voltage limiting circuit having a conduction threshold voltage.

26. The apparatus of claim 25 wherein the voltage limiting circuit includes a Zener diode having a first terminal coupled to the voltage step-down circuit and a second terminal coupled to ground.

27. The apparatus of claim 22, further comprising a detector circuit coupled to the voltage limiter to detect the transient overvoltage, the detector circuit defining a detection voltage threshold that the voltage to be regulated is to cross for the overvoltage to be detected, the detection voltage threshold being between the setpoint voltage and the first threshold voltage.

28. The apparatus of claim 27 wherein the detector circuit includes:
at least one transistor coupled to the voltage regulator;
at least one inverter coupled to the at least one transistor; and
a flip-flop coupled to said at least one inverter to generate an indication signal indicative of whether the overvoltage has been detected, wherein a number of said at least one transistor and of said at least one inverter is chosen so that the overvoltage causes said at least one inverter to switch if the voltage to be regulated reaches the detection threshold voltage, said flip-flop being responsive to said switching of the at least one inverter to change a state of said indication signal.

29. A system for regulating a direct voltage supplied by a voltage generator, the system comprising:
means for stopping or activating the voltage generator depending on whether the voltage to be regulated is greater or lower than a setpoint voltage; and
means for clipping a transient overvoltage greater than a first threshold voltage, the transient overvoltage appearing in the voltage to be regulated, the first threshold voltage being greater than the setpoint voltage.

30. The system of claim 29, further comprising:
means for detecting the transient overvoltage by comparing the voltage to be regulated with a detection threshold voltage, the detection threshold voltage being between the setpoint voltage and the first threshold voltage;
means for counting each detection of said transient overvoltage; and
means for storing the counted detections of said transient overvoltage.

31. The system of claim 29, further comprising memory load means for receiving said voltage, after said voltage has been regulated.
